(19) United States
(12) Patent Application Publication
(10) Pub. No.: US 2006/0197219 A1
(43) Pub. Date: Sep. 7, 2006

(54) HEAT SINK AND PACKAGE STRUCTURE

(76) Inventors: Chang-Chi Lee, Kaohsiung (TW); Tong-Hong Wang, Selangor D. E. (MY)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,629

(22) Filed: Jan. 4, 2006

(30) Foreign Application Priority Data
Jan. 13, 2005 (TW) 94100957

(51) Int. Cl. H01L 23/34

(52) U.S. Cl. 257/706

(57) ABSTRACT

A heat sink for conducting a coolant is provided. The heat sink includes a casing and a porous material layer. The porous material layer is disposed inside the casing, and the coolant is conducted into the porous material layer. Moreover, a package structure that dissipates heat by use of a coolant is provided. The package structure includes a carrier, a chip, and the aforementioned heat sink. The chip is disposed on the carrier, and the heat sink is disposed on the carrier or above the chip. The heat dissipation efficiency of the package structure can be improved by the heat sink.

### CROSS-REFERENCE TO RELATED APPLICATION

This application claims the priority benefit of Taiwan application serial no. 94100957, filed on Jan. 13, 2005. All disclosure of the Taiwan application is incorporated herein by reference.

### BACKGROUND OF THE INVENTION

1. Field of Invention

The present invention relates to a heat sink and a package structure. More particularly the present invention relates to a heat sink and a package structure having high heat dissipation efficiency.

2. Description of Related Art

Recently, with the continuous increase in the integration of the internal circuitry of the integrated circuit (IC), the heat produced by the IC is also increased continuously. For the personal computer, ICs with high integration, such as the Central Processing Unit or graphic chip, produce heat. To allow said ICs to continue normal operation, the IC must be kept under a preferable operating temperature, in order to avoid degradation of the performance or damage due to overheating. In other words, with the continuous improvement of the processing speed and the data processing capacity of the IC, the heat dissipation requirements are also needed to be enhanced relatively. Therefore, at present, some package structures have heat sinks.

As described above, since the heat sink in the conventional package structure is a passive heat dissipation element, in the situation in which the integration of the inner circuit of the chip is continuously increasing, the heat generated by the chip is also increased continuously. Therefore, the passive heat sink cannot meet the heat dissipation requirements of the chip.

### SUMMARY OF THE INVENTION

Accordingly, the present invention is directed to provide an active heat sink which dissipates heat mainly by use of a coolant so as to improve the heat dissipation efficiency of the heat sink.

The present invention is directed to provide a package structure, wherein an active heat sink is disposed on a carrier and the heat sink dissipates heat mainly by a coolant, in order to improve the heat dissipation efficiency of the package structure.

The present invention is directed to provide a package structure, wherein an active heat sink is disposed above the chip, and the heat sink dissipates heat mainly by a coolant in order to improve the heat dissipation efficiency of the package structure.

As embodied and broadly described herein, the present invention provides a heat sink suitable for conducting a coolant. This heat sink comprises a casing and a porous material layer. The porous material layer is disposed in the casing and the coolant is suitable to be conducted into the porous material layer.

As embodied and broadly described herein, the present invention further provides a package structure suitable for dissipating heat by use of a coolant. The package structure comprises a carrier, a chip, and a heat sink. The chip is disposed on the carrier and is electrically connected to the carrier, and the heat sink is disposed on the carrier. Moreover, the heat sink comprises a casing and a porous material layer. The porous material layer is disposed in the casing, and the coolant is suitable to be conducted into the porous material layer.

In an embodiment of the present invention, the above package structure, for example, further comprises an encapsulant for fixing the chip on the carrier.

In an embodiment of the present invention, the carrier is, for example, a leadframe comprising a die pad and a plurality of leads. The die pad has a first attaching surface and a corresponding first rear surface, wherein the chip is disposed on the first attaching surface and the heat sink is disposed on the first rear surface, and the leads are arranged around the die pad.

In an embodiment of the present invention, the carrier is, for example, a printed circuit board (PCB). Moreover, the carrier has, for example, a second attaching surface and a corresponding second rear surface, wherein the chip is disposed on the second attaching surface. Additionally, the heat sink is disposed, for example, on the second attaching surface of the carrier or on the second rear surface of the carrier. Furthermore, the chip and the heat sink are stacked, for example, on the second attaching surface of the carrier.

In an embodiment of the present invention, the above package structure further comprises, for example, a plurality of solder balls disposed on the second attaching surface of the carrier or the second rear surface of the carrier.

As embodied and broadly described herein, the present invention further provides a package structure suitable for dissipating heat by a coolant. The package structure comprises a carrier, a chip, and a heat sink. The chip is disposed on the carrier and is electrically connected to the carrier, and the heat sink is disposed above the chip. Moreover, the heat sink comprises a casing and a porous material layer, wherein the porous material layer is disposed in the casing and the coolant is suitable to be conducted into the porous material layer.

In an embodiment of the present invention, the above package structure further comprises, for example, an encapsulant for fixing the chip on the carrier. Moreover, the heat sink is embedded, for example, in the encapsulant above the chip.

In an embodiment of the present invention, the carrier is, for example, a leadframe. The leadframe comprises, for example, a die pad and a plurality of leads. The die pad has a first attaching surface and a corresponding first rear surface, and the chip is disposed on the first attaching surface. Moreover, the leads are arranged around the die pad.

In an embodiment of the present invention, the carrier is, for example, a PCB. The carrier has, for example, a second attaching surface and a corresponding second rear surface, wherein the chip is disposed on the second attaching surface.

In an embodiment of the present invention, the above package structure further comprises, for example, a plurality of solder balls disposed on the second attaching surface of the carrier or the second rear surface of the carrier.

In the above heat sink and the two package structures, the casing has, for example, an inlet and an outlet, wherein the coolant is injected into the porous material layer through the inlet and is output through the outlet. Moreover, the casing is, for example, a plate casing, a strip casing, a frame casing, or a U-shape casing. Additionally, the material of the casing is, for example, metal.

In the above heat sink and the two package structures, the material of the porous material layer is, for example, metal. Moreover, the porous material layer is, for example, a metal sinter.

In the heat sink of the present invention, the porous material layer has many pores, so the contact area between the coolant and the porous material layer are enlarged, thus enabling the coolant to dissipate the heat of the heat sink rapidly. Therefore, the heat sink of the present invention has high heat dissipation efficiency.

Moreover, since the above heat sink is disposed on the carrier or above the chip according to the package structure of the present invention, the heat sink can rapidly absorb the heat of the surface with which it is in contact and can rapidly dissipate the absorbed heat by use of a coolant. Therefore, the heat dissipation efficiency of the package structure according to the present invention is relatively high.

In order to the make the aforementioned and other objects, features and advantages of the present invention more comprehensible, preferred embodiments accompanied with appended drawings are described in detail below.

### BRIEF DESCRIPTION OF THE DRAWINGS

FIGS. 1A-1C are sectional views depicting three package structures according to one preferred embodiment of the present invention;

FIGS. 2A and 2B two sectional views depicting the heat sink;

FIG. 3 is a sectional view depicting another package structure according to one preferred embodiment of the present invention;

FIGS. 4A and 4B are sectional views depicting yet another two package structures according to one preferred embodiment of the present invention; and

FIGS. 5A and 5B are sectional views depicting still another two package structures according to one preferred embodiment of the present invention.

### DESCRIPTION OF EMBODIMENTS

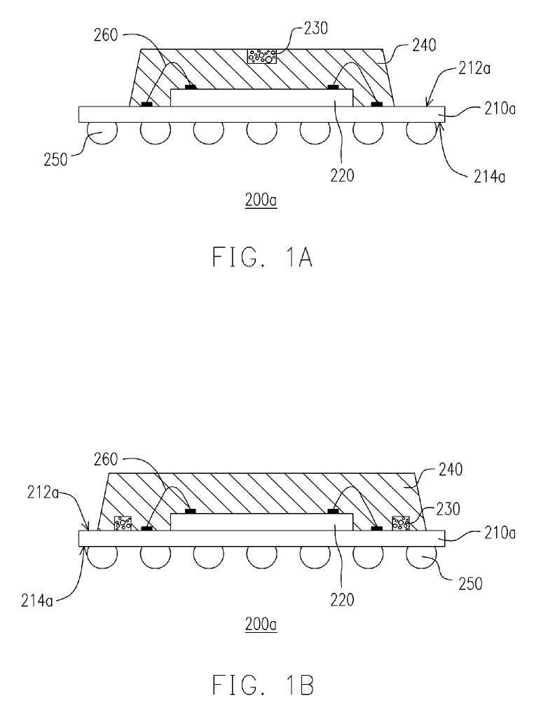

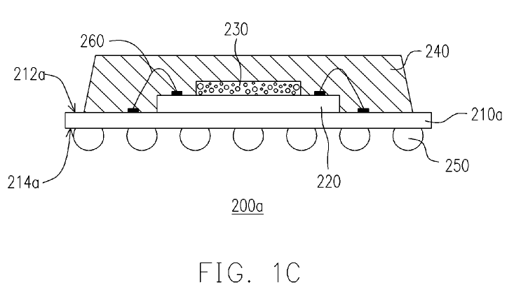

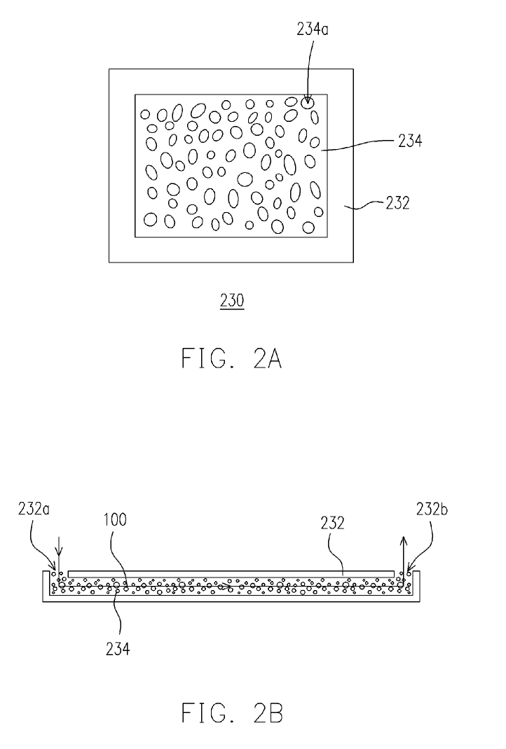

FIGS. 1A-1C are sectional views depicting three package structures according to one preferred embodiment of the present invention. FIG. 2A and FIG. 2B are two sectional views depicting the heat sink. Referring to FIGS. 1A, 1B, 2A, and 2B, a package structure 200a of the present embodiment is adapted to dissipate heat by a coolant (not shown). The package structure 200a comprises a carrier 210a, a chip 220, and a heat sink 230. The chip 220 is disposed on the carrier 210a and the heat sink 230 is disposed above the chip 220 (as shown in FIG. 1A) or on the carrier 210a (as shown in FIG. 1B). Moreover, the heat sink 230 comprises a casing 232 and a porous material layer 234, wherein the porous material layer 234 is disposed in the casing 232, and the coolant is adapted to be conducted into and flow within the porous material layer 234.

The above package structure 200a further comprises, for example, an encapsulant 240 for fixing the chip 220 on the carrier 210a. Moreover, the casing 232 of the heat sink 230 has, for example, an inlet 232a and an outlet 232b, and the coolant 100 is injected into the porous material layer 234 through the inlet 232a and is output through the outlet 232b.

As described above, since the heat sink 230 is disposed on the carrier 210a or above the chip 220 according to the package structure 200a of the embodiment, the casing 232 of the heat sink 230 can absorb the heat of the surface (the surface of the carrier or the encapsulant) contacting it. Moreover, since the porous material layer 234 has many pores 234a inside, when the coolant 100 is injected into the porous material layer 234 through the inlet 232a, the contact area between the coolant 100 and the porous material layer 234 is large, thus enabling the coolant 100 to absorb the heat of the heat sink 230 rapidly and then dissipate it. Therefore, the package structure 200a of the embodiment has high heat dissipation efficiency.

In the embodiment, the material of the casing 232 of the heat sink 230 is, for example, metal. Moreover, the material of the porous material layer 234 is, for example, sintered metal. In the embodiment, the metal is, for example, sintered into a metal sinter having many pores 234a, or the metal is made to have many pores 234a by penetrating or other methods to serve as the passage for passing the coolant 100.

It should be noted that the shape of the casing 232 depicted in the FIG. 2B is for the purpose of illustration only, and not for that of limiting the present invention. In fact, the casing 232 of the embodiment can be a strip casing, a plate casing, a frame casing, a U-shape casing, or a casing of another shape. Moreover, the package structure of the embodiment has various configurations, and a plurality of preferred configurations given below are for the purpose of illustration only, and not that of limiting the present invention. It should be known to any of those skilled in the art that proper modifications can be made according to the present invention without departing the scope of the invention.

Referring to FIGS. 1A-1C, in one preferred embodiment of the present invention, the carrier 210a can be a printed circuit board (PCB), a leadframe or other carriers. The carrier 210a depicted in the FIGS. 1A-1C is a PCB having a attaching surface 212a and a corresponding rear surface 214a. The chip 220 is disposed on the attaching surface 212a. Moreover, the heat sink 230 is, for example, embedded in the encapsulant 240 above the chip 220a (as shown in FIG. 1A), or is disposed on the attaching surface 212a of the carrier 210a (as shown in FIG. 1B). In addition, in one embodiment, the chip 220 and the heat sink 230 are, for example, stacked on the attaching surface 212a of the carrier 210a (as shown in FIG. 1C).

As described above, the package structure 200a of the embodiment further comprises, for example, a plurality of solder balls 250 disposed on the rear surface 214a of the carrier 210a. The package structure 200a is electrically connected to the other elements by the solder balls 250. Moreover, the package structure 200a further comprises, for example, a plurality of bonding wire 260 connected between the chip 220 and the carrier 210a, such that the chip 220 is electrically connected to the carrier 210a by the bonding wire 260. It should be noted that the bonding wire 260 of the embodiment can also be replaced by bumps (not shown).

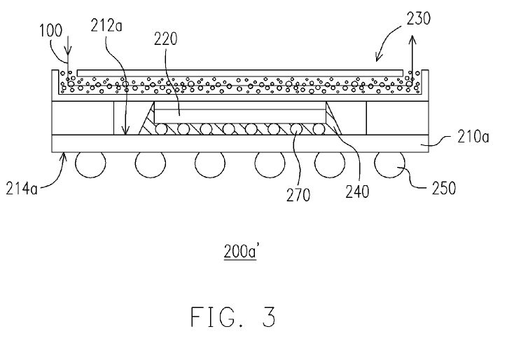

FIG. 3 is a sectional view depicting another package structure according to one preferred embodiment of the present invention. Referring to FIG. 3, in the package structure 200a′ of the present embodiment, the carrier 210a is, for example, a PCB having a attaching surface 212a and a rear surface 214a corresponding to the attaching surface 212a. The chip 220 is disposed on the attaching surface 212a and is electrically connected to the carrier 210a by the bump 270. Moreover, the heat sink 230 is disposed above the chip 220 and the solder balls 250 are disposed on the rear surface 214a of the carrier 210a.

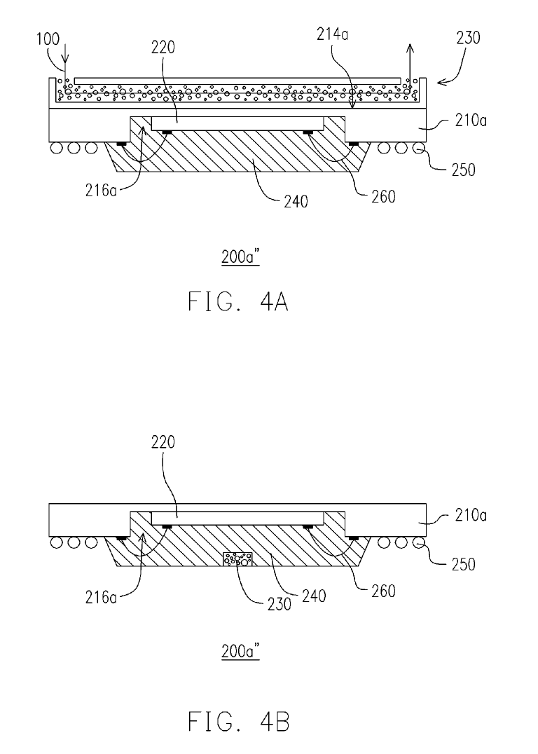

FIGS. 4A and 4B are sectional views depicting another two package structures according to one preferred embodiment of the present invention. Referring to FIGS. 4A and 4B, in the package structure 200a″ of the present embodiment, the carrier 210a is, for example, a PCB, wherein the attaching surface 212a thereof has a cavity 216a, and the chip 220 is disposed on the bottom of the cavity 216a. Moreover, the heat sink 230 is disposed on the rear surface 214a of the carrier 210a (as shown in FIG. 4A), or is disposed in the encapsulant 240 above the chip 220 (as shown in FIG. 4B). The solder balls 250 are disposed on the attaching surface 212a of the carrier 210a.

As described above, the heat sink 230 according to the package structure 200a″ of the present invention can be disposed on the attaching surface 212a of the carrier 210a (as shown in FIGS. 1B and 1C), on the rear surface 214a of the carrier 210a (as shown in FIG. 4A), above the chip 220 (as shown in FIG. 3), or embedded in encapsulant 240 above the chip 220 (as shown in FIGS. 1B and 4B). Moreover, the solder balls 250 can be disposed on the attaching surface 212a of the carrier 210a (as shown in FIGS. 4A and 4B) or on the rear surface 214a of the carrier 210a (as shown in FIGS. 1A-1C and FIG. 3).

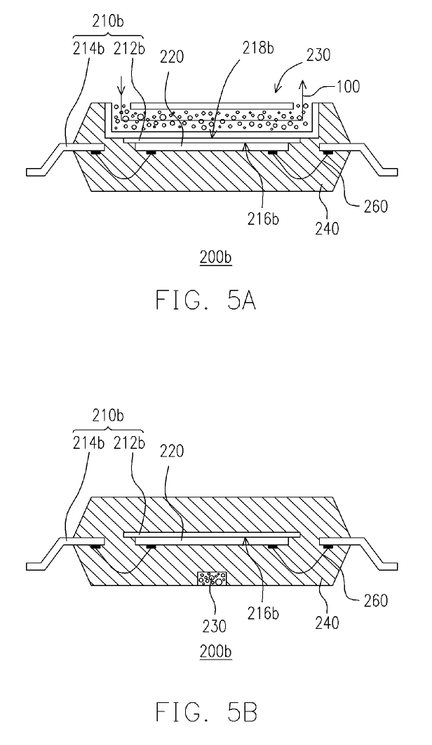

FIGS. 5A and 5B are sectional views depicting still another two package structures according to one preferred embodiment of the present invention. Referring to FIGS. 5A and 5B, in the package structure 200b of the present embodiment, the carrier 200b is, for example, a leadframe having a die pad 212b and a plurality of leads 214b. The chip 220 is disposed on the die pad 212b, and the leads 214b are arranged around the die pad 212b and are electrically connected to the chip 220. Moreover, the die pad 212b has, for example, a attaching surface 216b and a corresponding rear surface 218b. The chip 220 is disposed on the attaching surface 216b and the heat sink 230 is, for example, disposed on the rear surface 218b of the die pad 212b (as shown in FIG. 5A) or in the encapsulant 240 above the chip 220 (as shown in FIG. 5B).

The above package structure 200b further comprises, for example, a plurality of bonding wire 260 connected between the chip 220 and the leads 214b to make the chip 220 electrically connected to the lead 214b. Of course, the bonding wire 260 in the package structure 200b can be replaced by bumps (not shown).

It should be noted that, in the above various package structures 200a, 200a′, 200a″, and 200b, the shape of the casing of the heat sink 230 is not limited to the shapes shown in the drawings. That is, the casing can be a strip casing, a plate casing, a frame casing, a U-shape casing, or a casing of another shape.

In view of the above, the package structure of the present invention has at least the following advantages:

1. Since the porous material layer of the heat sink has many pores therein, the contact area between the coolant and the porous material layer can be enlarged, thus enabling the coolant to dissipate the heat of the heat sink rapidly. Therefore, the heat sink in the package structure of the present invention has high heat dissipation efficiency.

2. Since the heat sink is disposed on the carrier or above the chip, the heat sink with high heat dissipation efficiency can rapidly absorb the heat of the surface with which it is in contact, thus improving the heat dissipation efficiency of the package structure.

Although the present invention is disclosed as above by preferred embodiments, they are not intended to limit the present invention. Various variations and modifications can be made by any of those skilled in the art without departing from the spirit and scope of the present invention, and the scope of the present invention shall be defined by the appended claims.

What is claimed is:

1. A package structure suitable for dissipating heat by a coolant, comprising:
a carrier;
a chip disposed on the carrier and electrically connected to the carrier;
a heat sink disposed on the carrier, comprising:
a casing; and
a porous material layer disposed in the casing, wherein the coolant is suitable to be conducted into the porous material layer.

2. The package structure as claimed in claim 1, wherein the carrier comprises a leadframe, and the leadframe comprises:
a die pad having a first attaching surface and a corresponding first rear surface, wherein the chip is disposed on the first attaching surface, and the heat sink is disposed on the first rear surface; and
a plurality of leads arranged around the die pad.

3. The package structure as claimed in claim 1, wherein the carrier comprises a printed circuit board.

4. The package structure as claimed in claim 3, wherein the carrier comprises a second attaching surface and a corresponding second rear surface, and the chip is disposed on the second attaching surface and the heat sink is disposed on the second attaching surface or the second rear surface.

5. The package structure as claimed in claim 4, wherein the chip and the heat sink are stacked on the second attaching surface of the carrier.

6. The package structure as claimed in claim 1, wherein the casing has an inlet and an outlet, and the coolant is injected into the porous material layer through the inlet and is output through the outlet.

7. The package structure as claimed in claim 1, wherein the casing comprises a plate casing, a strip casing, a frame casing, or a U-shape casing.

8. The package structure as claimed in claim 1, wherein a material of the casing comprises metal.

9. The package structure as claimed in claim 1, wherein a material of the porous material layer comprises metal.

10. The package structure as claimed in claim 1, wherein the porous material layer comprises a metal sinter.

11. A package structure suitable for dissipating heat by a coolant, comprising:
a carrier;
a chip disposed on the carrier and electrically connected to the carrier;
a heat sink disposed above the chip, comprising:
a casing; and
a porous material layer disposed in the casing, wherein the coolant is suitable to be conducted into the porous material layer.

12. The package structure as claimed in claim 11, further comprising an encapsulant for fixing the chip on the carrier, wherein the heat sink is embedded in the encapsulant above the chip.

13. The package structure as claimed in claim 11, wherein the carrier comprises a leadframe, and the leadframe comprises:
a die pad having a first attaching surface and a corresponding first rear surface, wherein the chip is disposed on the first attaching surface; and
a plurality of leads arranged around the die pad.

14. The package structure as claimed in claim 11, wherein the carrier comprises a printed circuit board.

15. The package structure as claimed in claim 14, wherein the carrier has a second attaching surface and a corresponding second rear surface, and the chip is disposed on the second attaching surface.

16. The package structure as claimed in claim 11, wherein the casing has an inlet and an outlet, and the coolant is injected into the porous material layer through the inlet and is output through the outlet.

17. The package structure as claimed in claim 11, wherein the casing comprises a plate casing, a strip casing, a frame casing, or a U-shape casing.

18. The package structure as claimed in claim 11, wherein a material of the casing comprises metal.

19. The package structure as claimed in claim 11, wherein a material of the porous material layer comprises metal.

20. The package structure as claimed in claim 11, wherein the porous material layer comprises a metal sinter.
